(19) United States
(12) Patent Application Publication
(10) Pub. No.: US 2025/0309893 A1
(43) Pub. Date: Oct. 2, 2025

(54) CIRCUIT FOR SWITCH MATCHING

(71) Applicant: TEXAS INSTRUMENTS INCORPORATED, DALLAS, TX (US)

(72) Inventors: Kevin SCOONES, SAN JOSE, CA (US); Mustapha EL-MARKHI, RICHARDSON, TX (US)

(21) Appl. No.: 18/622,825

(22) Filed: Mar. 29, 2024

(51) Int. Cl. H03K 17/687

(52) U.S. Cl. CPC H03K 17/6871

(57) ABSTRACT

A circuit can include a first switch and a second switch. The first switch has first and second current terminals and a first control terminal, in which the first or second current terminal is coupled to a switch output. The second switch has third and fourth current terminals and a second control terminal, in which the second control terminal is coupled to the first control terminal, and the fourth current terminal is coupled to the switch output. A switch network is coupled between the first switch and the second switch.

### TECHNICAL FIELD

This description relates to switches, for example a circuit for switch matching.

### BACKGROUND

Mismatches between sensing circuitry and associated switches can arise over time due to different conditions experienced by the sensing circuitry and the switches. For example, a sense transistor can be coupled to a power transistor in a power converter and the sense transistor is configured to provide an indication of a sensed electrical parameter, such as a current or voltage. One or more operating parameters of the sense transistor and the power transistor can drift apart over time, such as due to being subjected to different amounts of stress and/or temperature.

### SUMMARY

An example circuit can include a first switch and a second switch. The first switch has first and second current terminals and a first control terminal, in which the first current terminal is coupled to a switch output. The second switch has third and fourth current terminals and a second control terminal, in which the second control terminal is coupled to the first control terminal, and the fourth current terminal is coupled to the switch output. A switch network is coupled between the first switch and the second switch.

Another example circuit includes a first transistor configured to conduct current through the first transistor between first and second current terminals thereof responsive to a control signal at a control input of the first transistor having a first value. A second transistor is coupled to the first transistor and configured to provide a sensor signal at a sensor output, in which the sensor signal is representative of the current through the first transistor responsive to the control signal. A switch network is coupled between at least one terminal of the second transistor and at least one terminal of the first transistor responsive to the control signal having a second value.

A further described example relates to an integrated circuit that includes a first transistor having first and second current terminals and a first control terminal. The integrated circuit also includes a plurality of second transistors, in which each of the second transistors has respective third and fourth current terminals and a second control terminal, and each second control terminal is coupled to the first control terminal. The first transistor occupies an area of the integrated circuit that is larger than each of the second transistors, and each of the second transistors is spatially distributed across the area occupied by the first transistor. A switch network is coupled between the first current terminal and at least some of the third current terminals. Sensing circuitry has a sensor input and a sensor output, in which the fourth current terminal of at least one of the second transistors is coupled to the sensor input.

### BRIEF DESCRIPTION OF THE DRAWINGS

FIG. 1 is a block diagram illustrating an example circuit.

FIG. 2 is a plan view of an integrated circuit illustrating an example distribution of components for a circuit.

FIG. 3 is a circuit diagram illustrating an example power converter.

FIG. 4 is a signal diagram illustrating examples of signals from the circuit of FIG. 3.

FIG. 5 is a circuit diagram illustrating an example of a power converter with sensing circuitry.

FIGS. 6 and 7 are graphs illustrating examples of parameter matching between a switch and sensing circuitry.

FIG. 8 is a graph showing an example of simulated drift between components over time.

FIG. 9 is a block diagram illustrating an example system that includes power converter circuitry.

### DETAILED DESCRIPTION

This description relates to reducing mismatch between switches, such as between switches in sensing circuitry and power switches.

As an example, a circuit includes one first switch (e.g., a transistor) configured to conduct current through the first switch responsive to a control signal having a first value (e.g., a value to turn on or close) the first switch. In some examples, the first switch can be a power switch, such as a field effect transistor (e.g., FET) that can be part of a bridge circuit, such as a half bridge of a power converter. A sensor, which includes one or more sensor switches (e.g., one or more transistors), is coupled to the first switch. The sensor switch(es) can be configured to provide a sensor signal representative of current through the first switch responsive to the control signal. The circuit also includes a switch network configured to couple at least one respective terminal of the sensor switch(es) to at least one respective terminal of the first switch responsive to the control signal having a second value (e.g., a value to turn off the first switch). The switch network enables the sensor switch(es) to be subjected to approximately the same voltage stress as the first switch, including when the first switch is turned off.

Also, or as an alternative example, the circuit is implemented as an integrated circuit (IC), in which the first switch is a first transistor and the sensor switch includes a plurality of sensor transistors. The switch network can also be implemented as an arrangement of sensor transistors in the same IC. The first transistor can occupy an area within the IC that is larger than the area occupied by each of the sensor transistors, individually or collectively, such as one or multiple orders of magnitude larger. To enable the sensor transistors to be subjected to approximately the same temperature stress as the first transistor, the sensor transistors (being smaller devices) reside in the same region of the IC as the first transistor, namely at respective locations spatially distributed across the area occupied the first transistor.

By implementing a layout and/or configuration of the circuit, as described herein, over time and responsive to operation of the circuit, the sensor switch(es) can be subjected to voltage and temperature stresses that approximate stresses on the first switch. As a result, potentially diverse effects of aging on the respective switches also can be reduced. For example, diverse aging effects, such as due to voltage and/or temperature stress, can change the drain-to-source on resistance (RDSon) of FETs if allowed to drift over time. Changes in RDSon between the first FET and the sense FET can decrease sensing accuracy and adversely affect performance of the circuit over time. The layout and/or inclusion of the switch network in the circuit can reduce these other effects of aging.

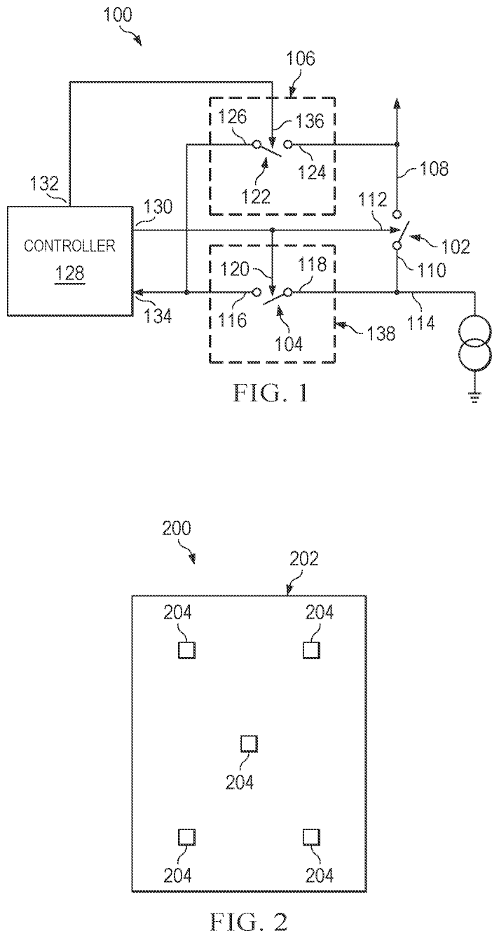

FIG. 1 illustrates an example circuit 100. In some examples, the circuit 100 can include or be implemented as a power converter or other type of circuitry. The circuit 100 includes switches 102 and 104 and a switch network 106. The switch (e.g., a transistor) 102 has current terminals 108 and 110 and a control terminal 112. In the example of FIG. 1, the current terminal 110 is coupled to a switch output 114, to which a load can be coupled. In other examples, the other current terminal 108 can be coupled to the switch output 114. The switch (e.g., one or more transistors) 104 has current terminals 116 and 118 and a control terminal 120. In some examples, the switch 104 is referred to as a sense switch. The control terminal 120 is coupled to the control terminal 112 of the switch 102, and the current terminal 118 is coupled to the current terminal 110 as well as to the switch output 114. In the example of FIG. 1, the switch network 106 includes a switch (e.g., transistor) 122 having terminals 124 and 126 coupled between the current terminals 108 and 116. Additionally, or in alternative examples, such as where the current terminal 108 is coupled to the switch output 114, the switch network 106 can be coupled between the current terminals 110 and 118.

A controller 128 has controller outputs 130 and 132 and a controller input 134. The controller output 130 is coupled to the control terminals 112 and 120 of the switches 102 and 104, respectively. The controller output 132 is coupled to a control input 136 of the switch 122. The controller input 134 is coupled to the current terminal 116 of the switch 104. The controller 128 is configured to provide respective control signals at the controller outputs 130 and 132 for controlling operation of the circuit 100. For example, the switch 102 is configured to conduct current through the first transistor between current terminals 108 and 110 responsive to the control signal at the control terminal 112 having a first value (e.g., a value to activate the switch to a closed position). The switch 104 can be implemented as part of sensing circuitry (e.g., a sensor) 138 configured to provide a sensor signal at the current terminal 116 responsive to the control signal at the control terminal 120. For example, the sensor signal is representative of the current through the switch 102 responsive to the control signal at 112.

The switch network 106 is configured to couple the terminal 116 of the switch 104 to the terminal 108 of the switch 102 respective terminal of the second transistor responsive to the control signal having a second value, which can be different from the first value. For example, the switch network 106 can couple one or more terminals 116, 118 of the switch 104 to respective terminals 108, 110 of the switch 102 responsive to the switch 102 being turned off. In this way, the switch 104, which is configured (e.g., as a sensor switch) for sensing current through the switch, can be subjected to substantially the same voltages as the switch 102.

While the example of FIG. 1 illustrates the switches 102, 104 and 122 as generic switches, one or more (e.g., all) of such switches can be implemented as transistors, such as FETs (e.g., p-channel or n-channel FETs). As further example, the switch 102 can be implemented as a power transistor, such as a gallium nitride (GaN) FET, a silicon carbide (SiC) FET, metal oxide semiconductor FET (e.g., MOSFET) or other FETs. Other types of transistors can be used to implement the switch 102 in other examples, such as a bipolar junction transistor (BJT) or an insulated gate bipolar transistor (IGBT). Similarly, each of the switches 104 and 122 can be implemented as one or more FETs or other types of transistors, which can be the same or different type of transistor from the type used to implement the switch 102. In some examples, the switch 104 includes one or more FETs, and the switch 102 is a power FET, in which the power FET has an area that is larger (e.g., one or more orders of magnitude larger) than each of the one or more FETs that define the switch 104. To reduce the effects of temperature variations, the FETs that constitute the switch 104 can be in the same tank as the power FET that constitutes the switch 102, such as evenly distributed across the area of the power FET. For example, the tank is an isolated well, such as an n-well or p-well, formed within an IC substrate containing the FETs that define switches 102 and 104.

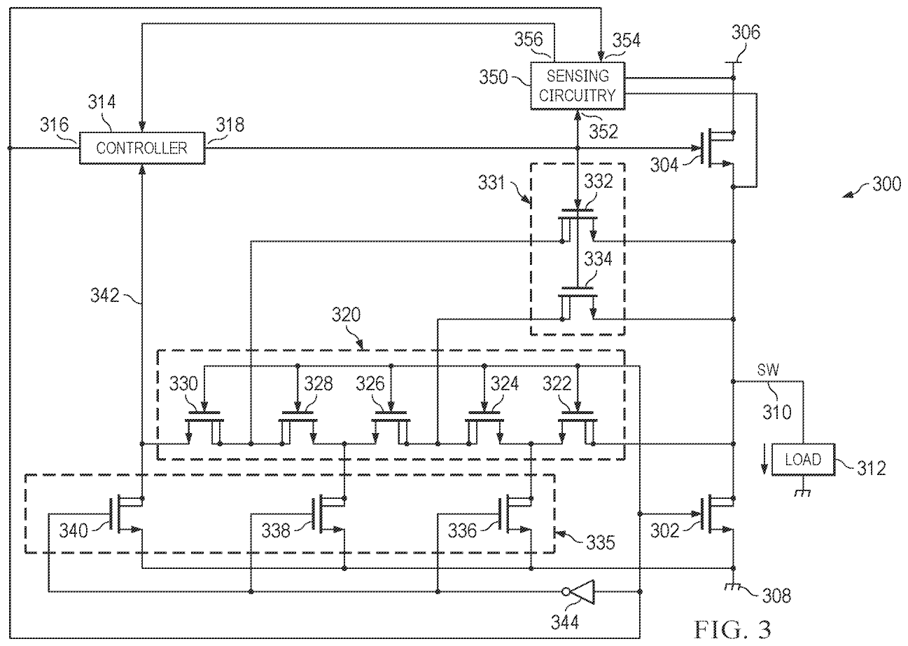

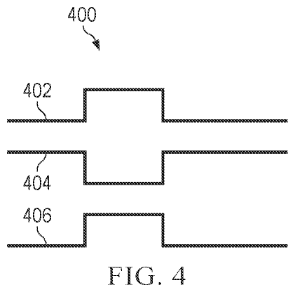

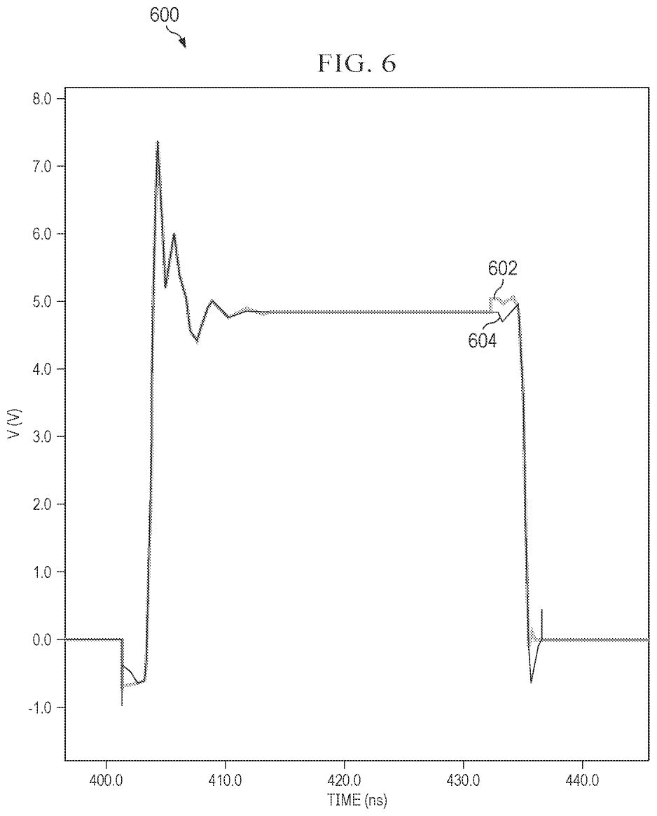

FIG. 2 is a plan view of an integrated circuit 200 illustrating an example distribution of components for a circuit, such as the circuit 100 of FIG. 1. In the example of FIG. 2, the integrated circuit 200 includes a transistor 202 (e.g., the switch 102) and a plurality of other transistors 204 (e.g., defining switch 104 of FIG. 1, switch 320 of FIG. 3, or switch 506 of FIG. 5). The transistors 202 and 204 can each be FETs or other types of transistors. For example, the transistor 202 occupies an area of the IC 200 that is that is larger than (e.g., several orders of magnitude larger) than the area of each of the transistors 204, and each of the transistors 204 is spatially distributed across the area occupied by the first transistor. In a further example, the first transistor (e.g., FET) 202 has an area that is at least one-hundred times larger than each of the second transistors (e.g., FETs) 204 (e.g., the transistor 202 can be 1000 to 100,000 times larger than transistors 204).

The transistor 202, which can be referred to as a main transistor, is formed in a semiconductor fabrication process within or including an n-well or p-well having an area that is larger than each of the transistors 204. During fabrication, each of the transistors 204 can also be formed within the area occupied by the same p-well or n-well constituting the transistor 202. There can be any number of one or more transistors 204 (e.g., 2, 3, 4, 5, 6, 7, 8 or more), which can be formed at respective locations across the area of the transistor 202. In the example of FIG. 2, five of the transistors 204 are evenly (e.g., uniformly) distributed across the area of the transistor 202, such as shown in the example of FIG. 2. A uniform distribution of the transistors 204 enables at least some of the transistors 204 to be subjected to temperature variations across the larger transistor 202. By implementing multiple transistors 204 in the same tank and evenly distributed across the area of the transistors 202, the transistors 204 can exhibit improved thermo-electrical matching to the main transistor 202 compared to existing configurations that typically include a single transistor at a respective location. In other examples, the transistors 204 are non-uniformly distributed within the area occupied by the transistor 202, such as localized more closely in one or more regions within the area occupied by the transistor 202.

FIG. 3 is a circuit diagram illustrating an example power converter (also referred to as a power circuit) 300. The power converter 300 can be used to implement the circuit 100 or the IC 200 of FIGS. 1 and 2, respectively. The power converter includes transistors (e.g., FETs) 302 and 304 coupled between a voltage supply terminal 306 and a ground terminal 308. For example, the transistors are power FETs configured as a bridge circuit (e.g., a half-bridge) having a switch output 310 to which a load 312 can be coupled and the power converter 300 can provide a regulated output (e.g., voltage and/or current). The load 312 can include a processor, a data storage device, an electric motor, a lighting system, an automotive system, a network infrastructure, audio and video devices, a robot, a computing device, or other type of load. The transistor 302 has a first current terminal (e.g., a drain) coupled to the switch output 310 and a second current terminal (e.g., a source) coupled to the ground terminal 308. The transistor 304 has a first current terminal (e.g., a drain) coupled to the voltage supply terminal 306 and a second current terminal (e.g., a source) coupled to the switch output 310. Each of the transistors 302 and 304 also has a respective control terminal (e.g., a respective gate).

A controller 314 has outputs 316 and 318 coupled to the control terminals of the respective transistors 302 and 304. The controller 314 is configured to provide control signals at 316 and 318 to control the power converter 300. The transistor 302 is configured to conduct current through the transistor and to the output responsive to the control signal at 316 having a given value. The transistor 304 is also configured to conduct current through the transistor and to the switch output 310 responsive to the control signal at 318 having a given value. For example, the value to turn on (e.g., a gate-to-source voltage to operate the transistor 314 in a saturation mode) the respective transistors 302, 304 can depend on the type of transistors implemented in the power converter 300, such as whether the transistors 302 and/or 304 are p-channel or n-channel metal oxide semiconductor (MOS) FETs or other types of FETs. The transistors 302 and 304 can be the same or different types of transistors.

The circuit also includes a switch (e.g., the switch 104) 320 that includes a plurality of transistors (e.g., FETs) 322, 324, 326, 328, and 330. Each of the transistors 322, 324, 326, 328, and 330 has a respective control terminal (e.g., a gate) coupled to the control terminal of the transistor 302. Each of the transistors 322, 324, 326, 328, and 330 also has a first current terminal (e.g., a drain) and a second current terminal (e.g., a source). In the example of FIG. 3, the first current terminal of the transistor 322 is coupled to the first terminal of the transistor 302. A first switch network 331 (e.g., part of switch network 106) includes transistors (e.g., FETs) 332 and 334 coupled between the first current terminal of each of the transistors 324, 326, 328, and 330 and the first terminal of the transistor 302. A second switch network 335 (e.g., another part of switch network 106) includes transistors (e.g., FETs) 336, 338, and 340 coupled between the second current terminal of each of the transistors 324, 326, 328, and 330 and the second terminal of the transistor 302 (also coupled to ground terminal 308).

In the example of FIG. 3, the transistor 332 is coupled between the first current terminal of the transistor 302 and a common first terminal (e.g., a common drain) of transistors 328 and 330, and the transistor 334 is coupled between the first current terminal of the transistor 302 a common first terminal (e.g., a common drain) of transistors 324 and 326. The control terminal (e.g., gate) of the transistors 332 and 334 are coupled to the control terminal of the transistor 304 (also coupled to the controller output 318), such that the transistors 332 and 334 receive the control signal provided at 318 for the transistor 304. The transistor 336 is coupled between the source of the transistor 302 and a common source of the transistors 322 and 324. The transistor 338 is coupled between the source of the transistor 302 and a common source of the transistors 326 and 328, and the transistor 340 is coupled between the source of the transistor 302 and the source of the transistor 330. An inverter 344 can be coupled between the control terminal (e.g., gate) of the transistor 302 and the control terminal (e.g., gate) of each of the transistors 336, 338, and 340 of the switch network 335, such that the control terminals of each of the transistors 336, 338, and 340 receive an inverted version of the control signal provided at 316 for the transistor 302.

The switch 320, which includes transistors (e.g., FETs) 322, 324, 326, 328, and 330, has a switch output 342 coupled to a sense input of the controller 314. The switch 320 is configured to sense current through the transistor 302 and provide a sensor signal at the switch output 342 responsive to the control signal provided at 316. For example, the sensor signal at 342 is a current signal representative of current through the transistor 302, which can be provided to sensing circuitry and loop control of the controller 314 for controlling the power converter 300. During operation of the power converter 300, in the absence of the switch networks 331 and 335, the switch 320, which includes transistors 322, 324, 326, 328, and 330, would be subjected to different electrical stress than the transistor 302, which is configured to operate as switch. The different electrical stress experienced by the switch 320 and the transistor 302 over time and due the effects of aging could degrade performance of the circuit.

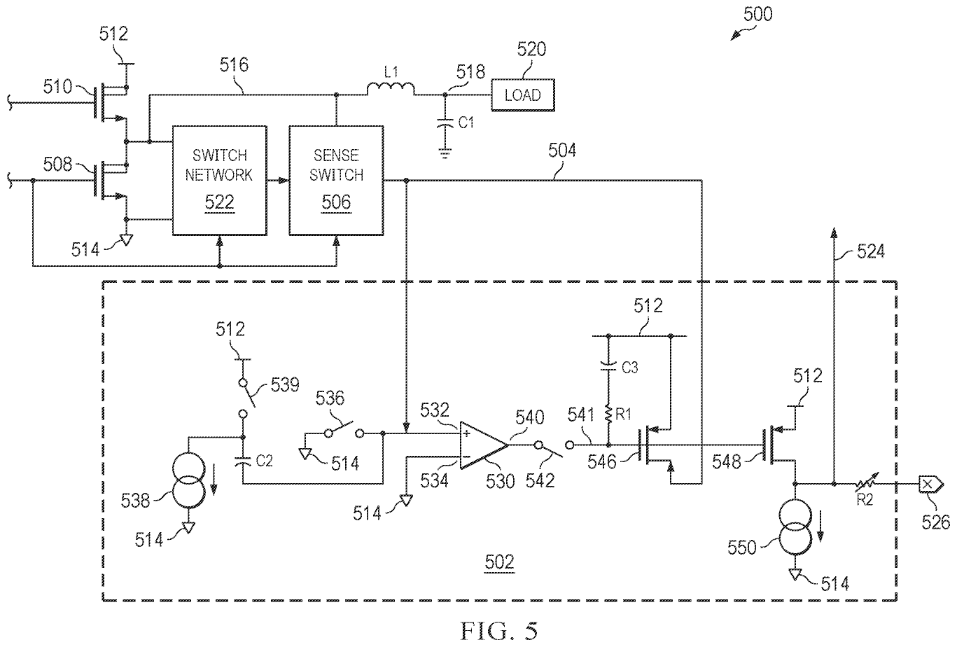

The transistors 332 and 334 of the switch network 331 are configured to couple one or more current terminals (e.g., drains) of the transistors 322, 324, 326, 328, and 330 to the corresponding current terminal (e.g., drain) of the transistor 302 responsive to the control signal at 318 (e.g., coupled to the gates of transistors 304, 332, and 334) having a value commanding the transistor 304 to turn on. Similarly, the transistors 336, 338, and 340 of the switch network 335 are configured to couple one or more current terminals (e.g., sources) of the transistors 322, 324, 326, 328, and 330 to the corresponding current terminal (e.g., source) of the transistor 302 responsive to an inverted version of the control signal at 316 (e.g., through inverter 344) coupled to the gate of transistors 336, 338, and 340) having a value commanding the transistor 302 to turn off. In some example operating modes, the controller 314 is configured to turn on the transistor 304 (e.g., operate the transistor 314 in a saturation mode) concurrently with (or after) the transistor 302 is turned off, such as shown in the diagram 400 of FIG. 4. The diagram 400 illustrates an example of the control signal at the output 318 going high, shown at 402, which is concurrent with the control signal at 316 going low, shown at 404. FIG. 4 also illustrates the signal 406, which is representative of the signal at the control inputs of transistors 336, 338, and 340 (e.g., an inverted version of the signal at 316).

In the example of FIG. 3, in which the transistors 302, 304, 322, 324, 326, 328, and 330 are FETs, the switch networks 331 and 335 can force the drain-to-source voltage and the gate-to-source voltage of the transistor 302 onto each of the transistors 322, 324, 326, 328, and 330 to reduce the effects of aging that might otherwise occur due to stress over time. Additionally, by implementing the common drain and common source configuration for the transistors 322, 324, 326, 328, and 330 of the switch 320, a reduced number of transistors can be used in the switch networks 331 and 335 to subject the transistors 322, 324, 326, 328, and 330 to the stress of the transistor 302. Therefore, the configuration according to the example shown in FIG. 3 can be efficiently implemented in a cost effective manner and provide improved performance compared to existing approaches.

In view of the foregoing, the switch 320 and switch networks 331, 335 can define an instance of sensing circuitry configured for sensing current through the transistor 302 in a manner that reduces effects of aging and thus can improve performance over time. Another instance of the sensing circuitry, shown as sensing circuitry 350, can be coupled to the transistor 304. The sensing circuitry 350 thus can be configured similarly to the sensing circuitry that is associated with the transistor, which is defined by 302, 331 and 335. The sensing circuitry 350 has inputs coupled to the first and second current terminals of the transistor 304. The sensing circuitry 350 can include a first control input 352 coupled to the control input of the transistor 304 (also coupled to the controller output 318). The sensing circuitry 350 can also include a second control input 354 coupled to the control output 316, which is also coupled to the control input of the transistor 302. The sensing circuitry 350 has an output 356 coupled to a sense input of the controller 314. The controller 314 is configured to control one or more sense transistors (e.g., FETs) of the sensing circuitry 350 to provide a signal representative of a current through the transistor 304 responsive to the control signal at 352 having a value commanding the transistor 304 to turn on. The sensing circuitry 350 also includes a switch network that is configured to couple current terminals of sense transistors to corresponding current terminals (e.g., the drain and source) of the transistor 304 responsive to the control signal at 352 having a value commanding the transistor 304 to turn off. Additionally, the sense transistors of the sensing circuitry can reside in the same tank (e.g., a well formed in an IC) and distributed over the area occupied by the larger transistor 304 to provide enhanced thermos-electrical matching. In this way, the sensing circuitry 350 can be subjected to electrical and thermal stresses that are commensurate with those of the transistor 304 such that performance can be improved compared to existing sensing approaches.

FIG. 5 is a circuit diagram illustrating an example of a power converter 500 that includes sensing circuitry (e.g., a sensor) 502 having an input coupled to an output 504 of one or more sense switch(es) 506. The example sensing circuitry 502 of FIG. 5 (or other sensing circuitry) can be used in combination with the circuit 100 or power converter 300 of FIG. 1 or 3, respectively, such as coupled to the output of switch 104 or the switch output 342 to receive a respective signal (e.g., current) being sensed. In examples where the sense switch 506 includes a plurality of transistors (e.g., transistors 322, 324, 326, 328, and 330, such as FETs), a current terminal (e.g., source or drain) of at least one of the second transistors is coupled to the output 504, which is coupled to the input of the sensing circuitry 502. In some examples, the sense switch 506 can be implemented as part of the sensing circuitry 502.

The power converter 500 includes transistors (e.g., switches) 508 and 510 coupled between a supply terminal 512 and a ground terminal 514. The voltage supply terminal can be coupled to a DC voltage (e.g., a voltage rail). The transistors 508 and 510 can be power FETs or other types of transistors configured as a bridge circuit (e.g., a half-bridge) having a switch output 516. An LC network, which includes an inductor L1 and a capacitor C1, can be coupled to between the switch output 516 and an output terminal 518 to which a load 520 can be coupled. The load 520 can include a processor, a data storage device, an electric motor, a lighting system, an automotive system, a network infrastructure, audio and video devices, a robot, a computing device, or other type of load. The power converter 500 can be configured to provide a regulated output (e.g., voltage and/or current) at the output terminal 518. The sense switch 506 has first and second inputs, in which the first input is coupled to the switch output 516 and the second input is coupled to the control input of the transistor 508. In an example, the sense switch 506 is implemented according to the example switch 104 or 320 described with respect to FIGS. 1 and 3, respectively. Other switch configurations can be used in other examples.

The power converter 500 also includes a switch network 522. In some examples the switch network 522 is implemented according to the switch networks 331 and 335 of FIG. 3. The switch network 522 can be implemented in other configurations, such as may be indicated by the use environment of the power converter 500. The switch network 522 has inputs coupled to respective current terminals of the transistor 508, and one or more other inputs coupled to the control input of the transistor 508 and/or the control input of the transistor 510. As described herein, the switch network 522 is configured to subject the sense switch 506 (or multiple sense switches) to electrical stress that is commensurate with the stress experienced by the transistor 508. The sense switch 506 is also configured to provide a signal (e.g., a current) at the output 504 representative of current through the transistor 508 responsive to a control signal at the control input of the transistor having a value commanding the transistor to turn on.

As described herein, the sensing circuitry 502 has an input coupled to the output 504 of the sense switch 506. The sensing circuitry 502 includes outputs 524 and 526. The sensing circuitry 502 is configured to provide a sense signal at each of the sensor outputs 524 and 526 representative of current through the transistor (e.g., switch) 508. For example, the output 524 is coupled to an input of a controller (e.g., the controller 128 or 314), which can be implemented in the same IC with the other components of the power converter 500, and the output 526 can be coupled to an output terminal of the IC.

In the example of FIG. 5, the sensing circuitry 502 includes an amplifier (e.g., an operational-amplifier) 530 having a first input 532 and a second input 534, in which the first input 532 is coupled to the output 504 and the second input 534 is coupled to the ground terminal 514. A switch 536 is coupled between the first input and the ground. A capacitor (e.g., a DC blocking capacitor) C2 is coupled with a current source 538 in series between the first amplifier input 532 and the ground terminal 514. Another switch 539 is coupled between the current source 538 and the supply terminal 512. As a further example, each of the switches is closed when the switch network is activated to perform stress matching between the sense switch 506 and the transistor 508, such as responsive to control signals from the controller. Responsive to the switches 536 and 539 being closed the amplifier inputs are reset (e.g., zeroed out) to initial values and the capacitor C2 is precharged. Each of the switches 536 and 539 can open responsive to (e.g., during sensing) to allow the signal at 504 to be measured and scaled to desired output values at 524 and 526, as described herein.

The amplifier 530 has an output 540 coupled to an input 541 of an output stage of the sensing circuitry through a switch 542. That is, the switch is coupled between the output 540 of the amplifier 530 and the input 541 of the output stage. The amplifier 530 is configured to amplify the sense signal at 532 to provide an amplified sense signal. The output stage includes an RC network, which includes a resistor R1 and a capacitor C3, coupled between the input 541 of the output stage and the supply terminal 512. The input 541 is coupled to a control input (e.g., gate) of a transistor (e.g., a FET) 546. The transistor 546 has a first current terminal (e.g., a drain) coupled to the output 504 of the sense switch 506 and a second current terminal (e.g., a drain) coupled to the supply terminal 512. The RC network thus is coupled between the control terminal and second current terminal of the transistor 546. The output of the switch 542 is also coupled to a control input of another transistor (e.g., a FET) 548. The transistor 548 has a first current terminal (e.g., a drain) coupled to the output 524 of the sensing circuitry and a second current terminal (e.g., a drain) coupled to the supply terminal 512. The first current terminal of the transistor 548 is also coupled to the ground terminal 514 through a current source 550 and to the output 526 through a resistor, such as a variable resistor R2.

In an example, each of the transistors 546 and 548 are PMOS FETs and form a current mirror configured to mirror the amplified sense signal at 541 to the respective outputs 524 and 526. The switch 542 is configured to close responsive to a control signal at the control input of the transistor having a value commanding the transistor to turn on (e.g., during sensing). As a result, the amplifier output signal at 540 is provided to the control terminals of the transistors 546 and 548 to mirror the amplified signal to the outputs 524 and 526.

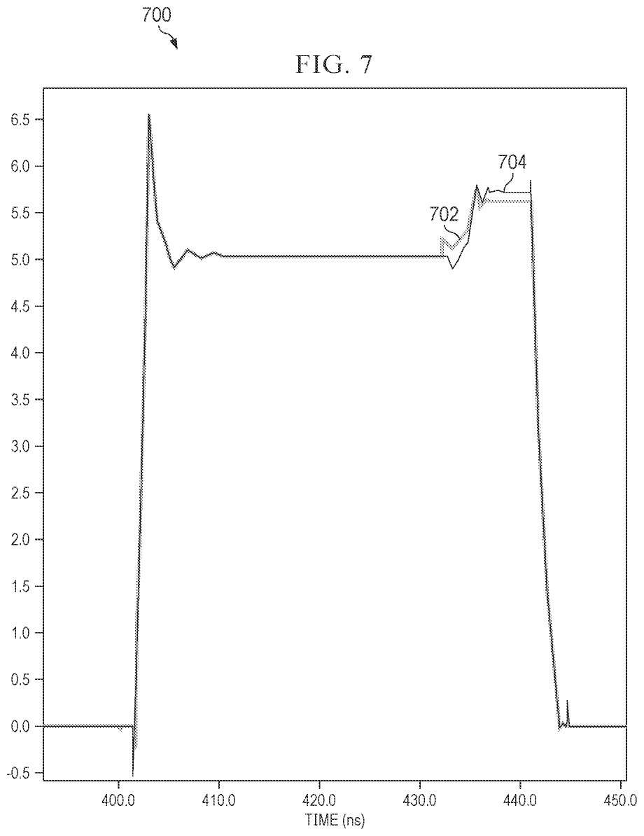

FIGS. 6 and 7 are plots 600 and 700 illustrating examples of parameter matching between a switch and sensing circuitry for different load conditions. The plots 600 and 700 signal for the power converter of FIG. 3. In FIG. 6, the signal 602 shows drain-to-source voltage across each of the transistors 322, 324, 326, 328, and 330 and the signal 604 shows the drain-to-source voltage across the transistor 302 for a 25 A load condition. In FIG. 7, the signal 702 shows drain-to-source voltage across each of the transistors 322, 324, 326, 328, and 330 and the signal 704 shows the drain-to-source voltage across the transistor 302 for a −5 A load condition. FIGS. 6 and 7 thus demonstrate that the rising and falling edges of the voltages signals closely match each other, which is a result of the switch networks 331 and 335.

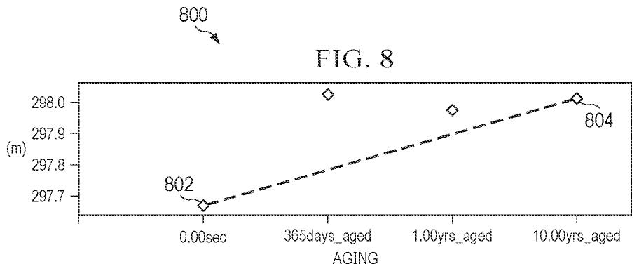

FIG. 8 is a plot 800 showing examples of current provided by the switch 320 (including transistors 322, 324, 326, 328, and 330) in the circuit of FIG. 3 over time, which is shown logarithmically on the x-axis for an aging period of time from 0 seconds to 10 years. The example of FIG. 8 assumes that the on-resistance of the transistor 302 has degraded approximately 8-9% over the aging period and that the current being measured through the transistor 302 remains at 25 A. A comparison of the measure of current for a sensed current of 25 A at 0 seconds, shown at 802, and the measure of current at 10 years, shown at 804, demonstrates as shift in the sensed measure of current of only about 0.1%, which indicates that the stress matching circuitry described herein is effective.

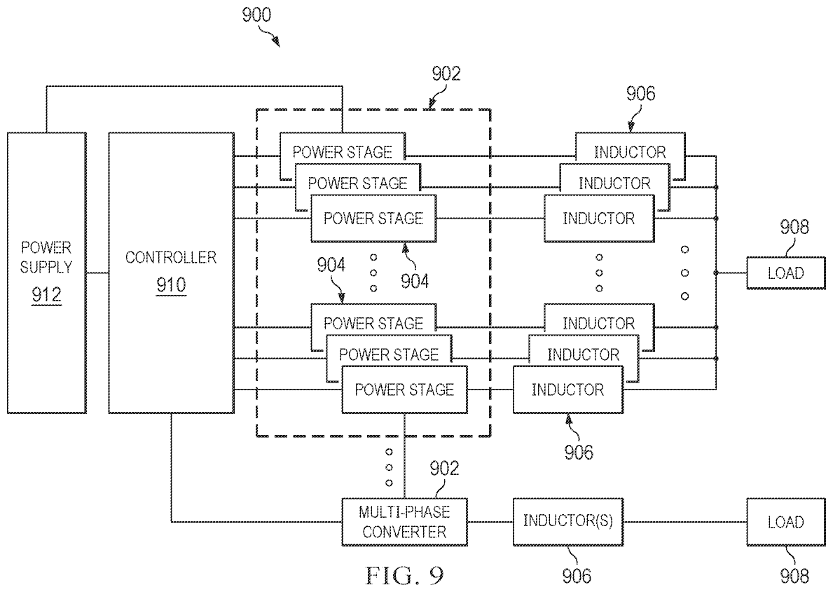

FIG. 9 is a block diagram illustrating an example system 900 that includes power converter circuitry described herein for a given use environment. The power converter circuitry includes one or more multi-phase power converters 902, in which each phase of the multi-phase power converter can include a power stage 904. Each power stage 904 can include an instance of a power converter described herein (e.g., circuit 100, power converter 300, or power converter 500). For example, each power stage 904 can include one or more power transistors (e.g., arranged as a bridge circuit) and sensing circuitry (e.g., 106 and 138 of FIG. 1; 320, 331, and 335 or 350 of FIG. 3; or 502, 506, 522 of FIG. 5) coupled to one or more of the power transistors, as described herein.

In the example of FIG. 9, each power stage 904 has an output coupled through an inductor 906 to a respective load 908. The load can be a CPU and/or memory or other type of load, such as described herein. The multi-phase power converters 902 can be used to supply power to other types of loads in other examples. Additionally, the system 900 can include one or more controllers 910 configured to control each power stage 904, such as described herein, to provide regulated power to the load for each phase thereof. The controller 910 can be implemented as an instance of the controller 128 or 314 of FIG. 1 or 3, respectively. A power supply 912 can also be configured to provide centralized power to each multi-phase power converter 902.

In this description, the term “based on” means based at least in part on.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A circuit, comprising:
a first switch having first and second current terminals and a first control terminal, in which the first current terminal is coupled to a switch output;
a second switch having third and fourth current terminals and a second control terminal, in which the second control terminal is coupled to the first control terminal, and the fourth current terminal is coupled to the switch output; and
a switch network coupled between the first switch and the second switch.

2. The circuit of claim 1, further comprising a third switch having fifth and sixth current terminals and a third control terminal, in which the first current terminal is coupled to the switch output, the switch network is coupled between the second and fourth current terminals, the fifth current terminal is coupled to a voltage supply terminal, and the sixth current terminal is coupled to the first current terminal of the first switch.

3. The circuit of claim 2, wherein:
the first switch comprises a first field effect transistor (FET),
the third switch comprises a third FET,
the first and fifth current terminals are respective drains,
the second and sixth current terminals are respective sources, and
the first and third control terminals are respective gates.

4. The circuit of claim 3, wherein:
the second switch comprises a plurality of second FETs, in which each of the second FETs has a respective gate coupled to the gate of the first FET,
the switch network comprises:
a fourth switch coupled between a drain of at least some of the second FETs and the drain of the first FET, and
a fifth switch coupled between a source of at least some of the second FETs and the source of the first FET.

5. The circuit of claim 4, wherein:
the fourth switch comprises a plurality of fourth FETs, each having a respective gate coupled to the gate of the third FET, and
the fifth switch comprises a plurality of fifth FETs.

6. The circuit of claim 5, further comprising a controller having a first controller output coupled to the gate of the first FET, and a second controller output coupled to the gate of the third FET and to respective gates of the third FETs.

7. The circuit of claim 6, wherein:
the controller is configured to provide first and second control signals,
the first FET is configured to conduct current through the first FET responsive to the first control signal having a first value,
the third FET is configured to conduct current through the third FET responsive to the second control signal having a first value,
the plurality of fourth FETs are configured to couple the drain of the first FET to the drain of at least some of the second FETs responsive to the second control signal having the first value, and
the plurality of fifth FETs are configured to couple the source of the first FET to the source of at least some of the second FETs responsive to the first control signal having a second value.

8. The circuit of claim 4, wherein the first FET has an area that is at least one-hundred times larger than each of the second FETs.

9. The circuit of claim 8 implemented as an integrated circuit, wherein the plurality of second FETs resides in a region of the integrated circuit the first FET at respective locations spatially distributed across the area of the first FET.

10. The circuit of claim 1, further comprising sensing circuitry having a sensor input and a sensor output, in which the sensor input of the sensing circuitry is coupled to the switch output, and the sensing circuitry is configured to provide a sense signal at the sensor output representative of current through the first switch.

11. The circuit of claim 10, wherein the sensing circuitry comprises:
an amplifier having first and second amplifier inputs and an amplifier output, in which the first amplifier input is coupled to the switch output, the second amplifier input is coupled to a ground terminal;
a capacitor coupled to a current source in series between the first amplifier input and the ground terminal; and
a current mirror coupled between the amplifier output and the sensor output,
wherein the amplifier is configured to amplify the sense signal, and the current mirror is configured to provide an output current at the sensor output based on the amplified sense signal.

12. A circuit, comprising:
a first transistor configured to conduct current through the first transistor between first and second current terminals thereof responsive to a control signal at a control input of the first transistor having a first value;
a second transistor coupled to the first transistor and configured to provide a sensor signal at a sensor output, the sensor signal representative of the current through the first transistor responsive to the control signal; and
a switch network coupled between at least one terminal of the second transistor and at least one terminal of the first transistor responsive to the control signal having a second value.

13. The circuit of claim 12, wherein the control signal is a first control signal, and the circuit further comprises a third transistor, in which the third transistor is configured to conduct current through the third transistor between third and fourth current terminals thereof responsive to a second control signal having a respective value, and the fourth current terminal is coupled to the first current terminal.

14. The circuit of claim 13, wherein the switch network comprises:
a first switch configured to couple the first current terminal of the first transistor to a fifth current terminal of the second transistor responsive to the second control signal having the respective value; and
a second switch configured to couple the second current terminal of the first transistor to a sixth current terminal of the second transistor responsive to the first control signal having the second value.

15. The circuit of claim 14, wherein:
the first transistor comprises a first field effect transistor (FET), in which the first current terminal is a drain and the second current terminal is a source of the first FET,
the second transistor comprises a plurality of second FETs, in which each of the second FETs has a respective gate coupled to a gate of the first FET,
the third transistor comprises a third FET, in which the third current terminal is a drain and the fourth current terminal is a source of the third FET,
the first switch comprises a plurality of fourth FETs coupled between a drain of at least some of the second FETs and the drain of the first FET, and
the second switch comprises a plurality of fifth FETs coupled between a source of at least some of the second FETs and the source of the first FET.

16. The circuit of claim 15, further comprising a controller configured to transmit the first control signal to a gate of the first FET and the second control signal to respective gates of the second FETs, wherein:
the plurality of fourth FETs are configured to couple the drain of the first FET to respective drains of the at least some of the second FETs responsive to the second control signal having the respective value, and
the plurality of fifth FETs are configured to couple the source of the first FET to respective sources of the at least some of the second FETs responsive to the first control signal having the second value.

17. The circuit of claim 15 implemented as an integrated circuit, wherein:
the first FET is a power FET having an area that is at least one-hundred times larger than each of the second FETs, and
the plurality of second FETs resides in the same tank as the power FET at respective locations spatially distributed across the area of the power FET.

18. An integrated circuit, comprising:
a first transistor having first and second current terminals and a first control terminal;
a plurality of second transistors, in which each of the second transistors has respective third and fourth current terminals and a second control terminal, each second control terminal is coupled to the first control terminal, the first transistor occupies an area of the integrated circuit that is larger than each of the second transistors, and each of the second transistors is spatially distributed across the area occupied by the first transistor;
a switch network coupled between the first current terminal and at least some of the third current terminals; and
sensing circuitry having a sensor input and a sensor output, in which the fourth current terminal of at least one of the second transistors is coupled to the sensor input.

19. The integrated circuit of claim 18, further comprising:
a third transistor having fifth and sixth current terminals and a third control terminal, in which the fifth current terminal is coupled to a voltage supply terminal, and the sixth current terminal is coupled to the first current terminal.

20. The integrated circuit of claim 19, wherein:
the first transistor is a first field effect transistor (FET),
the plurality of second transistors comprises a plurality of second FETs in the same tank as the first FET uniformly spatially distributed across the area occupied by the first FET, and each of the second FETs has a respective gate coupled to a gate of the first FET,
the third transistor is a third FET, and
the switch network comprises:
a fourth FET coupled between a drain of the first FET and a drain of at least some of the second FETs; and
a fifth FET coupled between a source of the first FET and a source of at least some of the second FETs.
